(19) United States
(12) Patent Application Publication
(10) Pub. No.: US 2012/0308775 A1
(43) Pub. Date: Dec. 6, 2012

(54) HYDROPHILIC SURFACES AND PROCESS FOR PREPARING

(76) Inventors: Seung M. You, Arlington, TX (US); Miguel A. Amaya, Euless, TX (US)

(21) Appl. No.: 13/313,290

(22) Filed: Dec. 7, 2011

Related U.S. Application Data
(60) Provisional application No. 61/421,285, filed on Dec. 9, 2010.

(51) Int. Cl. B32B 15/20; B05D 3/02; C23C 16/44; B32B 5/16; B32B 15/04; B32B 33/00; B05D 7/14; B05D 5/00; B82Y 30/00

(52) U.S. Cl. 428/148; 427/180; 427/372.2; 427/248.1; 427/318; 428/457; 428/379; 428/34.1; 428/370; 977/773

(57) ABSTRACT

Disclosed are processes for forming hydrophilic surfaces on aluminum and aluminum substrates having highly hydrophilic surfaces.

### PRIORITY

This application claims the benefit of Provisional Application Ser. No. 61/421,285 filed on Dec. 9, 2010, the entirety of which is incorporated herein by reference.

### FIELD

Disclosed are processes for forming hydrophilic surfaces on aluminum and aluminum substrates having highly hydrophilic surfaces.

### BACKGROUND

Aluminum is the earth's most abundant metal and its use is ubiquitous. Global production of aluminum metal in 2005 was 31.9 million tons. One well known use of aluminum is the manufacture of cooling devices, inter alia, heat exchangers, cooling coils, and other evaporative devices. The efficiency of heat exchange on a surface is directly related to the ability of a cooling medium, for example, water, to efficiently and uniformly spread along the surface of a heated substrate. Untreated aluminum provides satisfactory resistance to corrosion by cooling media; however, the surface wettability of aluminum has been found to be less than adequate for many applications involving continuous and efficient heat transfer in the presence of a cooling medium. As such, manufacturers of aluminum have long sought to modify the surface, and thus the properties, of aluminum.

The Boehmite process has long been known. Boehmite is an aluminum oxide hydroxide mineral. Boehmite has been used to modify the surface of aluminum to increase its wetability. This coating process, which involves boiling aluminum in a hot water bath to form an oxide layer, although effective in creating a more hydrophilic surface, provides only a transient change in surface hydrophilicity due to the aging of the coating.

Therefore there continues to be a long felt need for processes and coatings which can provide increased hydrophilicity to aluminum surfaces with enhanced long-term reliability.

### BRIEF DESCRIPTION OF THE FIGURES

FIG. 1A is an optical microscope image of untreated aluminum, whereas FIG. 1B is an optical microscope image of an aluminum surface treated with the “nanocoating process” as further described herein. FIG. 1C is an image of aluminum which surface has been modified by the disclosed process.

FIG. 2A is a scanning electron microscope image of an aluminum surface modified by the Boehmite process. FIG. 2B is a scanning electron microscope image of an aluminum surface modified by the “nanocoating process.” FIG. 2C is a scanning electron microscope image of an aluminum surface modified by the disclosed process. FIG. 2D is a further magnification of the surface depicted in FIG. 2C showing

FIG. 3 depicts the change in contact angle of a drop of water on aluminum surfaces over time. Untreated aluminum (□) shows no change in contact angle over time indicating the hydrophobic nature of untreated aluminum. Aluminum treated with a nanocoating (o) provides an initial low contact angle but immediately reaches the contact angle limit. Aluminum treated by the disclosed process (♦) continues to spread over time.

FIG. 4 is an enlargement of the change in contact angle for aluminum treated with a nanocoating (o) versus aluminum treated by the disclosed process (♦). As depicted, the contact angle for a water droplet on the surface formed by the disclosed process approaches 0° within 15 seconds.

FIGS. 5A to 5D are photographs depicting the spreading of a 21 μL water droplet over various surfaces after 2 seconds of contact. FIG. 5A shows the spreading of a droplet over untreated aluminum wherein the contact angle, θ, was measured to be 99°. FIG. 5B shows the spreading of a droplet over aluminum treated with a nanocoating by the prior art process wherein the contact angle, θ, was measured to be 14°. FIG. 5C shows the spreading of a droplet over aluminum receiving only treatment with hot water wherein the contact angle, θ, was measured to be 22°. FIG. 5D shows the spreading of a droplet over aluminum which surface has been modified by the disclosed process wherein the contact angle, θ, was measured to be 4°.

FIG. 6A is an optical microscope image of an aluminum surface modified by the disclosed process prior to applying a tape peel test. FIG. 6B is an optical microscope image of the surface depicted in FIG. 6A showing that the modified surface peals adhesive from the tape during the tape peel test and the modified surface remains unchanged. FIG. 6C is an optical microscope image of the tape used in testing the surface depicted in FIG. 6A showing the loss of adhesive.

FIG. 7A is an optical microscope image of an aluminum surface coated with nanoparticles according to a prior art process before applying a tape peel test. FIG. 7B shows that the surface depicted in FIG. 7A loses a part of the coating during the tape peel test and FIG. 7C shows adhesive did not peel off the tape. The adhesive can still be seen on the surface of the tape.

FIG. 8 depicts the reliability of the surfaces prepared by the disclosed process to retain their highly hydrophilic properties over time without aging. The Boehmite process represented by (o) begins to lose its hydrophilic properties within 10 days, whereas surfaces prepared by the disclosed process (♦) retain their superior hydrophilic properties for months without change.

### DETAILED DESCRIPTION

The materials, compounds, compositions, articles, and methods described herein may be understood more readily by reference to the following detailed description of specific aspects of the disclosed subject matter and the examples included therein. Before the present materials, compounds, compositions, articles, devices, and methods are disclosed and described, it is to be understood that the aspects described below are not limited to specific synthetic methods or specific reagents, as such may, of course, vary. It is also to be understood that the terminology used herein is for the purpose of describing particular aspects only and is not intended to be limiting.

Also, throughout this specification, various publications are referenced. The disclosures of these publications in their entireties are hereby incorporated by reference into this application in order to more fully describe the state of the art to which the disclosed matter pertains. The references disclosed are also individually and specifically incorporated by reference herein for the material contained in them that is discussed in the sentence in which the reference is relied upon.

### General Definitions

In this specification and in the claims that follow, reference will be made to a number of terms, which shall be defined to have the following meanings:

All percentages, ratios and proportions herein are by weight, unless otherwise specified. All temperatures are in degrees Celsius (° C.) unless otherwise specified.

The terms “alumina” and “aluminum oxide,” both represented by the formula Al₂O₃, are used interchangeably in the present disclosure and stand equally well for one another.

The term “ceramic material” means inorganic, non-metallic material oxides that can be crystalline or partially crystalline in form that can be applied to the surfaces disclosed further herein. One type of ceramic materials is the transition metal oxides, inter alia, zinc oxide. Ceramic materials can also comprise “semi-aluminum substrates” or “aluminum composite substrates” as defined herein below.

As used in the present disclosure, the term “aluminum substrate” means any surface that comprises aluminum metal. Aluminum substrates include any material that comprises 100% by weight of aluminum metal. Aluminum substrates also include any composite materials that comprise at least one aluminum metal surface, for example, a sheet, pipe, baffle and the like that comprises another metal or non-metal that is coated with aluminum metal. One non-limiting example is a copper pipe that has been coated on the inside, on the outside, or both with aluminum metal. Another non-limiting example is an aluminum pipe which outside surface has been treated, for example, has been coated with a resin or has another metal coated thereon. As such, aluminum substrate relates to any material having at least one aluminum metal surface or at least a part of one or more surfaces comprising aluminum metal. Terms such as “pipe,” “sheet,” “baffle” and the like refer to the shape of the aluminum substrate and not to the composition itself.

As used in the present disclosure, the term “semi-aluminum substrate” or “aluminum composite substrate” means any surface that comprises less than about 100% of aluminum metal. Semi-aluminum substrates also include any composite materials that comprise at least one semi-aluminum metal surface, for example, a sheet, pipe, baffle and the like that comprises another metal or non-metal that is coated with a semi-aluminum composition. One non-limiting example is a pipe comprising an aluminum alloy, especially wherein the alloy comprises greater than 50% by weight of aluminum metal. In one embodiment, the alloy comprises greater than about 75% by weight of aluminum metal. In a further embodiment, the alloy comprises greater than 99% by weight of aluminum. In a still further embodiment, the alloy comprises greater that 99.9% by weight of aluminum.

The term “nanofluid” means a composition comprising one or more nanoparticles, i.e., alumina, ceramic material, etc. and one or more carriers as disclosed further herein below.

A weight percent of a component, unless specifically stated to the contrary, is based on the total weight of the formulation or composition in which the component is included.

“Admixture” or “blend” is generally used herein means a physical combination of two or more different components

By “reduce” or other forms of the word, such as “reducing” or “reduction,” is meant lowering of an event or characteristic (e.g., contact angle). It is understood that this is typically in relation to some standard or expected value, in other words it is relative, but that it is not always necessary for the standard or relative value to be referred to.

Throughout the description and claims of this specification the word “comprise” and other forms of the word, such as “comprising” and “comprises,” means including but not limited to, and is not intended to exclude, for example, other additives, components, integers, or steps.

As used in the description and the appended claims, the singular forms “a,” “an,” and “the” include plural referents unless the context clearly dictates otherwise. Thus, for example, reference to “a composition” includes mixtures of two or more such compositions, reference to “a nanoparticle composition” includes mixtures of two or more sizes or forms of aluminum oxide, reference to “the aluminum oxide coating” includes mixtures of two or more such types or forms of aluminum oxide, and the like.

“Optional” or “optionally” means that the subsequently described event or circumstance can or cannot occur, and that the description includes instances where the event or circumstance occurs and instances where it does not.

Ranges can be expressed herein as from “about” one particular value, and/or to “about” another particular value. When such a range is expressed, another aspect includes from the one particular value and/or to the other particular value. Similarly, when values are expressed as approximations, by use of the antecedent “about,” it will be understood that the particular value forms another aspect. It will be further understood that the endpoints of each of the ranges are significant both in relation to the other endpoint, and independently of the other endpoint. It is also understood that there are a number of values disclosed herein, and that each value is also herein disclosed as “about” that particular value in addition to the value itself. For example, if the value “10” is disclosed, then “about 10” is also disclosed. It is also understood that when a value is disclosed, then “less than or equal to” the value, “greater than or equal to the value,” and possible ranges between values are also disclosed, as appropriately understood by the skilled artisan. For example, if the value “10” is disclosed, then “less than or equal to 10” as well as “greater than or equal to 10” is also disclosed. It is also understood that throughout the application data are provided in a number of different formats and that this data represent endpoints and starting points and ranges for any combination of the data points. For example, if a particular data point “10” and a particular data point “15” are disclosed, it is understood that greater than, greater than or equal to, less than, less than or equal to, and equal to 10 and 15 are considered disclosed as well as between 10 and 15. It is also understood that each unit between two particular units are also disclosed. For example, if 10 and 15 are disclosed, then 11, 12, 13, and 14 are also disclosed.

### Process

Disclosed herein is a process for preparing hydrophilic surfaces on aluminum including aluminum substrates, i.e., sheets of aluminum, pipes comprising aluminum, or any substrate comprising aluminum such as aluminum parts or components used as part of an assemble or article of manufacture comprising materials other than aluminum.

The disclosed process comprises:
a) applying to aluminum a nanoparticle coating; and
b) fixing the nanoparticle coating to the aluminum.

In one aspect, the disclosed process comprises:
a) contacting an aluminum substrate with a composition comprising:
   i) aluminum oxide; and
   ii) one or more carriers;
to form a nanoparticle coating on the aluminum substrate; and
   b) fixing the coating by heating the aluminum substrate in a fixing solution.

In a further aspect, the disclosed process comprises:
a) heating an aluminum substrate;
b) contacting the aluminum substrate with a composition comprising:
   i) aluminum oxide; and
   ii) one or more carriers;
to form a nanoparticle coating on the aluminum substrate: and
c) fixing the coating by heating the substrate in a fixing solution.

In another aspect, the disclosed process comprises:
a) contacting an aluminum substrate with a composition comprising:
   i) aluminum oxide; and
   ii) one or more carriers;
to form a nanoparticle coating on the aluminum substrate;
b) heating the aluminum substrate; and
c) fixing the coating by contacting the substrate with a fixing solution.

### Step A: Application of a Nanoparticle Coating

Step A of the disclosed process relates to depositing onto an aluminum substrate a nanoparticle coating of aluminum oxide. The aluminum oxide nanoparticle coating can have the formula Al₂O₃ or any variation thereof depending upon the temperature at which the coating is applied, the size of the nanoparticles, or the carrier used. For example, the coating can be characterized as AlO(OH). Any form of aluminum oxide can be used to provide the final hydrophilic coating and the disclosed process is not dependent upon the absolute form of the aluminum oxide prior to step A.

Step A comprises contacting an aluminum substrate with a nanofluid. The nanofluid comprises:
i) a source of aluminum oxide; and
ii) one or more carriers.
   The source of aluminum oxide can comprise alumina, ceramic material, or mixtures thereof. In one aspect the average size of the nanoparticles is less than about 100 nanometers.

In another aspect, the size of the nanoparticles is less than about 100 nanometers (100 nm) in diameter. In one embodiment of this aspect, the nanoparticles are from about 50 nm to about 100 nm. In one embodiment of this aspect, the nanoparticles are from about 10 nm to about 90 nm. In another embodiment of this aspect, the nanoparticles are from about 20 nm to about 50 nm. In a further embodiment of this aspect, the nanoparticles are from about 30 nm to about 70 nm. In a still further embodiment of this aspect, the nanoparticles are from about 10 nm to about 36 nm. In a yet another embodiment of this aspect, the nanoparticles are from about 40 nm to about 80 nm. In a still yet further embodiment of this aspect, the nanoparticles are from about 35 nm to about 95 nm.

The disclosed process relates to contacting the aluminum substrate with a nanofluid comprising one or more carriers. In one aspect the carrier is an alcohol. In one embodiment the alcohol is methanol. In another embodiment the alcohol is ethanol. In a further embodiment the alcohol is isopropanol. In a yet another embodiment the alcohol is propanol. Non-limiting examples of other alcohols include n-butyl alcohol, isobutyl alcohol, n-pentyl alcohol, isopentyl alcohol, and the like. In some iterations the formulator can utilize halogenated alcohols, for example, 2,2,2-trichlorethanol.

In another aspect the carrier is water. In a further embodiment the carrier is an admixture of water and one or more alcohols. The alcohol/water admixtures can comprise in one embodiment at least about 5% water. In another embodiment of this aspect the carrier can comprise from about 1% to about 99% by weight of water. In a further embodiment of this aspect the carrier can comprise from about 10% to about 80% by weight of water. In a still further embodiment of this aspect the carrier can comprise from about 5% to about 99% by weight of water. In a yet another embodiment of this aspect the carrier can comprise from about 10% to about 40% by weight of water. In a yet still further embodiment of this aspect the carrier can comprise from about 40% to about 70% by weight of water.

The carrier can comprise other solvents, non-limiting examples of which include formic acid, acetic acid; alcohols, for example, ketones, for example, acetone, methyl ethyl ketone, diethyl ketone, and the like; esters, for example, methyl acetate, ethyl acetate, methyl propionate, ethyl propionate, and the like; ethers, for example, diethyl ether, methyl tert-butyl ether, tetrahydrofuran, dimethoxyethane, bis(2-methoxyethyl) ether (diglyme), 1,4-dioxane,and the like; alkanes, for example, pentane, isopentane, petroleum ether, hexane, mixtures of hexanes, cyclohexane, heptanes, isoheptane, octane, isooctane, and the like; halogenated solvents, for example, dichloromethane, chloroform, carbon tetrachloride, 1,1-dichloroethane, 1,1,1-trichloroethane, 1,2-dichloroethane, chlorobenzene, and the like; aromatic hydrocarbons, for example, benzene, toluene, 1,2-dimethylbenzene (ortho-xylene), 1,3-dimethylbenzene (meta-xylene), 1,4-dimetylbenzene (para-xylene), nitrobenzene, and the like; dipolar aprotic solvents, for example, acetonitrile, dimethylsulfoxide, N,N-di-methylformamide, N,N-diethylformamide, N,N-dimethylacetamide, N,N-diethylacetamide, N-methyl-2-pyrrolidinone, carbon disulfide, and hexamethylphosphoramide; and mixtures of one or more solvents.

The nanofluid can comprise from about 0.01 g/L to about 2 g/L of alumina, ceramic material, or mixtures thereof. In one aspect the nanofluid comprises from about 0.01 g/L to about 2 g/L of alumina. In one embodiment of this aspect, the nanofluid comprises from about 0.025 g/L to about 1.5 g/L of alumina In another embodiment of this aspect, the nanofluid comprises from about 0.5 g/L to about 1.5 g/L of alumina In a further embodiment of this aspect, the nanofluid comprises from about 0.025 g/L to about 1 g/L of alumina In a yet another embodiment of this aspect, the nanofluid comprises from about 0.1 g/L to about 1.5 g/L of alumina. In a still further embodiment of this aspect, the nanofluid comprises from about 0.1 g/L to about 1 g/L of alumina. The nanofluid can comprise any amount of alumina within the ranges disclosed herein, for example, 0.025, 0.026, 0.027, 0.028, 0.029, 0.030, 0.031, 0.032, 0.033, 0.034, 0.035, 0.036, 0.037, 0.038, 0.039, 0.040, 0.041, 0.042, 0.043, 0.044, 0.045, 0.046, 0.047, 0.048, 0.049, 0.050, 0.051, 0.052, 0.053, 0.054, 0.055, 0.056, 0.057, 0.058, 0.059, and 0.060 g/L of alumina

The nanofluid can comprise from about 0.01 g/L to about 2 g/L of one or more ceramic materials. In one aspect the nanofluid comprises from about 0.01 g/L to about 2 g/L of one or more ceramic materials. In one embodiment of this aspect, the nanofluid comprises from about 0.025 g/L to about 1.5 g/L of one or more ceramic materials. In another embodiment of this aspect, the nanofluid comprises from about 0.025 g/L to about 1.5 g/L of one or more ceramic materials. In a further embodiment of this aspect, the nanofluid comprises from about 0.025 g/L to about 1 g/L of one or more ceramic materials. In a yet another embodiment of this aspect, the nanofluid comprises from about 0.5 g/L to about 1.5 g/L of one or more ceramic materials. In a still further embodiment of this aspect, the nanofluid comprises from about 0.1 g/L to about 1 g/L of one or more ceramic materials. The nanofluid can comprise any amount of one or more ceramic materials within the ranges disclosed herein, for example, 0.025, 0.026, 0.027, 0.028, 0.029, 0.030, 0.031, 0.032, 0.033, 0.034, 0.035, 0.036, 0.037, 0.038, 0.039, 0.040, 0.041, 0.042, 0.043, 0.044, 0.045, 0.046, 0.047, 0.048, 0.049, 0.050, 0.051, 0.052, 0.053, 0.054, 0.055, 0.056, 0.057, 0.058, 0.059, and 0.060 g/L of one or more ceramic materials.

The nanofluid can comprise from about 0.01 g/L to about 2 g/L of an admixture of alumina and one or more ceramic materials. In one aspect the nanofluid comprises from about 0.01 g/L to about 2 g/L of an admixture of alumina and one or more ceramic materials. In one embodiment of this aspect, the nanofluid comprises from about 0.025 g/L to about 1.5 g/L of an admixture of alumina and one or more ceramic materials. In another embodiment of this aspect, the nanofluid comprises from about 0.025 g/L to about 1.5 g/L of an admixture of alumina and one or more ceramic materials. In a further embodiment of this aspect, the nanofluid comprises from about 0.025 g/L to about 1 g/L of an admixture of alumina and one or more ceramic materials. In a yet another embodiment of this aspect, the nanofluid comprises from about 0.1 g/L to about 1.5 g/L of an admixture of alumina and one or more ceramic materials. In a still further embodiment of this aspect, the nanofluid comprises from about 0.1 g/L to about 1 g/L of an admixture of alumina and one or more ceramic materials. The nanofluid can comprise any amount of an admixture of alumina and one or more ceramic materials within the ranges disclosed herein, for example, 0.025, 0.026, 0.027, 0.028, 0.029, 0.030, 0.031, 0.032, 0.033, 0.034, 0.035, 0.036, 0.037, 0.038, 0.039, 0.040, 0.041, 0.042, 0.043, 0.044, 0.045, 0.046, 0.047, 0.048, 0.049, 0.050, 0.051, 0.052, 0.053, 0.054, 0.055, 0.056, 0.057, 0.058, 0.059, and 0.060 g/L of an admixture of alumina and one or more ceramic materials. Within this aspect, alumina can comprise from about 0.01% to about 99.99% by weight of the admixture.

The substrate can be contacted with the nanofluid for any time desired by the formulator. In one aspect the substrate is contacted with the nanofluid for at least about 1 hour. According to this aspect the aluminum substrate can be contacted with a nanofluid for a time of from about 1 minute to about 60 minutes. In one embodiment the time is from about 1 minute to about 10 minutes. In another embodiment the time is from about 0.5 minute to about 2 minutes. In a further embodiment the time is from about 2 5 minute to about 4 minutes. In a still further embodiment the time is from about 30 seconds to about 1 minute. In a yet another embodiment the time is from about 3 minutes to about 4,5 minutes. In a still yet further embodiment the time is from about 15 seconds to about 30 seconds. The formulator can adjust the immersion time in the nanofluid based upon other process step variables, i.e., nanoparticle size, concentration, carrier, desired thickness of nanoparticle coating, and combinations thereof.

As described herein below, the formulator can vary the time for applying the nanocoating according to the desired characteristics of the coating.

Specific examples of a suitable nanofluid comprising the disclosed nanoparticles include the following:

TABLE I

| | Concen- | | | Concen- | |
|---|---|---|---|---|---|
| | tration | | | tration | |
| nanoparticle | g/L | carrier | nanoparticle | g/L | carrier |
| alumina | 0.025 | methanol | alumina | 0.025 | ethanol |
| alumina | 0.05 | methanol | alumina | 0.05 | ethanol |
| alumina | 0.075 | methanol | alumina | 0.075 | ethanol |
| alumina | 0.1 | methanol | alumina | 0.1 | ethanol |
| alumina | 0.2 | methanol | alumina | 0.2 | ethanol |
| alumina | 0.3 | methanol | alumina | 0.3 | ethanol |
| alumina | 0.4 | methanol | alumina | 0.4 | ethanol |
| alumina | 0.5 | methanol | alumina | 0.5 | ethanol |
| alumina | 0.6 | methanol | alumina | 0.6 | ethanol |
| alumina | 0.7 | methanol | alumina | 0.7 | ethanol |
| alumina | 0.8 | methanol | alumina | 0.8 | ethanol |
| alumina | 0.9 | methanol | alumina | 0.9 | ethanol |
| alumina | 1 | methanol | alumina | 1 | ethanol |
| alumina | 0.025 | water | alumina | 0.025 | ethanol (aq) |
| alumina | 0.05 | water | alumina | 0.05 | ethanol (aq) |
| alumina | 0.075 | water | alumina | 0.075 | ethanol (aq) |
| alumina | 0.1 | water | alumina | 0.1 | ethanol (aq) |
| alumina | 0.2 | water | alumina | 0.2 | ethanol (aq) |
| alumina | 0.3 | water | alumina | 0.3 | ethanol (aq) |
| alumina | 0.4 | water | alumina | 0.4 | ethanol (aq) |
| alumina | 0.5 | water | alumina | 0.5 | ethanol (aq) |
| alumina | 0.6 | water | alumina | 0.6 | ethanol (aq) |
| alumina | 0.7 | water | alumina | 0.7 | ethanol (aq) |
| alumina | 0.8 | water | alumina | 0.8 | ethanol (aq) |
| alumina | 0.9 | water | alumina | 0.9 | ethanol (aq) |
| alumina | 1 | water | alumina | 1 | ethanol (aq) |

Ethanol (aq) comprises from about 50% to about 99% by weight of ethanol adjusted for the desired consistency and properties of the composition.

### Evaporative Method

In one aspect of the disclosed process an aluminum substrate is first contacted with a composition comprising aluminum oxide and one or more carriers (nanofluid) wherein the aluminum oxide is deposited as a thin film on the substrate. The substrate is immersed in and removed from the aluminum oxide comprising solution. The immersion time is determined by the formula and depending upon the desired properties of the coating can be from sufficient time to just coat the substrate or to insure a pre-determined amount. Alternately, the nanofluid can be sprayed as a mist over the substrate, or the nanofluid can be spin-coated onto the substrate. The formulator can adjust the spray parameters (total volume, mist size, etc.) and spin coating parameters (rpm, spinning time) based upon other process step variables. The wet substrate is then allowed to dry (the carrier is allowed to evaporate) or the wet substrate is heated to increase the rate of evaporation. The contacting and drying cycle can be repeated as many times as desired by the formulator.

Contact of the substrate with the nanofluid can take place at a nanofluid temperature of from about 20° C. to about 100° C. In one embodiment the temperature is from about 50° C. to about 100° C. In another embodiment the temperature is from about 60° C. to about 100° C. In a further embodiment the temperature is from about 70° C. to about 100° C. In a still further embodiment the temperature is from about 80° C. to about 100° C. In a yet another embodiment the temperature is from about 90° C. to about 100° C. In a still yet further embodiment the temperature is from about 50° C. to about 80° C. The formulator can adjust the solution temperature depending upon the composition of the carrier to any range up to boiling. The substrate can be heated to evaporate the nanofluid that wets the substrate by contacting the substrate with a heated surface, or by placing the substrate in a heated environment. The temperature of the heated surface or of the heated environment can be from about 40° C. to about 100° C. In one embodiment the temperature is from about 50° C. to about 100° C. In another embodiment the temperature is from about 60° C. to about 100° C. In a further embodiment the temperature is from about 70° C. to about 100° C. In a still further embodiment the temperature is from about 80° C. to about 100° C. In a yet another embodiment the temperature is from about 90° C. to about 100° C. In a still yet further embodiment the temperature is from about 50° C. to about 80° C.

The formulator can adjust the contacting and drying temperatures based upon other process step variables, i.e., nanoparticle size, concentration, carrier, desired thickness of nanoparticle coating, and combinations thereof.

### Quenching Method

Another aspect of the disclosed process relates to the use of the quenching method for contacting the aluminum substrate with a composition comprising aluminum oxide and one or more carriers (nanofluid). The quenching method comprises at least one step wherein the aluminum substrate is heated to a temperature above the temperature of the nanofluid. The heated aluminum substrate is then immersed into the nanofluid for a period of time determined based upon the desired coating properties then withdrawn. At a minimum, the period of time is enough for boiling to begin and cease over the substrate as the substrate cools down in the cooler nanofluid. The nanoparticle coating is formed during this transient boiling. The heating and immersion cycle can be repeated as many times as desired by the formulator.

In one aspect of the disclosed quenching process an aluminum substrate is contacted with a composition comprising aluminum oxide and one or more carriers (nanofluid) wherein the nanofluid is at a temperature of from about 20° C. to about 100° C. In one embodiment the nanofluid temperature is from about 50° C. to about 100° C. In another embodiment the nanofluid temperature is from about 60° C. to about 100° C. In a further embodiment the nanofluid temperature is from about 70° C. to about 100° C. In a still further embodiment the nanofluid temperature is from about 80° C. to about 100° C. In a yet another embodiment the nanofluid temperature is from about 90° C. to about 100° C. In a still yet further embodiment the nanofluid temperature is from about 50° C. to about 80° C. The formulator can adjust the nanofluid temperature depending upon the composition of the carrier to any range within the boiling range or below.

The aluminum substrate is preheated to a temperature sufficiently high to cause boiling over the substrate once it is immersed in the cooler nanofluid. The formulator adjusts the preheating temperature or the initial temperature of the substrate to a temperature above the temperature of the nanofluid. The substrate can be preheated to an initial temperature of from about 40° C. to 500° C. In one embodiment the initial temperature is from about 100° C. to 150° C. In another embodiment the temperature is from about 200° C. to 400° C. In a further embodiment the temperature is from about 70° C. to about 300° C. In a still yet further embodiment the temperature is from about 300° C. to about 500° C. The formulator can adjust the initial temperature based upon other process step variables, i.e., nanoparticle size, concentration, carrier, nanofluid temperature, desired thickness of nanoparticle coating, and combinations thereof. As such, the number of times the aluminum substrate is quenched depends upon these variables.

### Step B: Fixing the Nanoparticle Coating

Step B of the disclosed process relates to fixing the nanoparticle coating on the aluminum substrate. In one aspect, the substrate comprising a nanocoating is heated in a fixing solution. In one embodiment the fixing solution comprises water. In one iteration of this embodiment the coated aluminum substrate formed in Step A is contacted with a heated solution of water. In one embodiment the temperature of the hot water is approximately 100° C. In another embodiment the temperature is from about 80° C. to about 100° C. In a further embodiment the temperature is from about 90° C. to about 100° C. In yet another embodiment the temperature is from about 95° C. to about 100° C. In a yet further embodiment the temperature is from about 90° C. to about 95° C. The temperature of the water can have any value, for example, 80° C., 81° C., 82° C., 83° C., 84° C., 85° C., 86° C., 87° C., 88° C., 89° C., 90° C., 91° C., 92° C., 93° C., 94° C., 95° C., 96° C., 97° C., 98° C., 99° C., and 100° C.

The substrate comprising the nanoparticle coating can be contacted with the fixing solution for any time desired by the formulator. In one aspect the substrate is contacted with the fixing solution for at least about 1 hour. According to this aspect the nanoparticle-coated aluminum substrate can be contacted with a fixing solution for a time of from about 1 minute to about 60 minutes. In one embodiment the time is from about 10 minute to about 60 minutes. In another embodiment the time is from about 25 minute to about 60 minutes. In a further embodiment the time is from about 25 minute to about 40 minutes. In a still further embodiment the time is from about 30 minutes to about 60 minutes. In a yet another embodiment the time is from about 30 minutes to about 45 minutes. In a still yet further embodiment the time is from about 15 minute to about 30 minutes. The formulator can adjust the immersion time in the fixing bath based upon other process step variables, i.e., nanoparticle size, concentration, carrier, desired thickness of nanoparticle coating, and combinations thereof.

### Hydrophilic Aluminum Substrate

The following describes the aluminum substrates that can be obtained by the disclosed process. The aluminum substrates thus coated have an increased hydrophilicity and therefore provide for a greater dispersion of fluids which contact the treated surface, i.e., lower contact angles and quicker spreading of the fluid (greater wettability).

Wettability refers to the shape the fluid, for example, water assumes in response to the chemical and structural properties of the surface that it contacts. A conventional measure of this response is the static contact angle. Geometry dictates that the more a given amount of water spreads over a surface; the lower is its contact angle. Therefore, a 90° contact angle or above is classified as nonwetting or hydrophobic since it indicates that the water does not spread but aggregates into hemispherical droplets. A contact angle of 0° is the theoretical limit of wettability or hydrophilicity, since it means that the water has spread infinitely and that the thickness of the spreading water is infinitesimally thin. The nanoporous layer created by the disclosed process can be classified as superhydrophilic because it yields equilibrium contact angles that approach 0°.

The disclosed hydrophilic aluminum substrates have one or more surfaces such that when a water droplet is contacted with the disclosed surface, the measured contact angle is less than about 10° in 2 seconds. In another aspect when a 21 μL drop of water is contacted with a disclosed hydrophilic surface, the measured contact angle is less than about 8° in 2 seconds. In a further aspect when an approximately 20 μL drop of water is contacted with a disclosed hydrophilic surface, the measured contact angle is less than about 5° in 10 seconds. In a still further aspect when a drop of water is contacted with a disclosed hydrophilic surface, the measured contact angle is less than about 4° in 20 seconds.

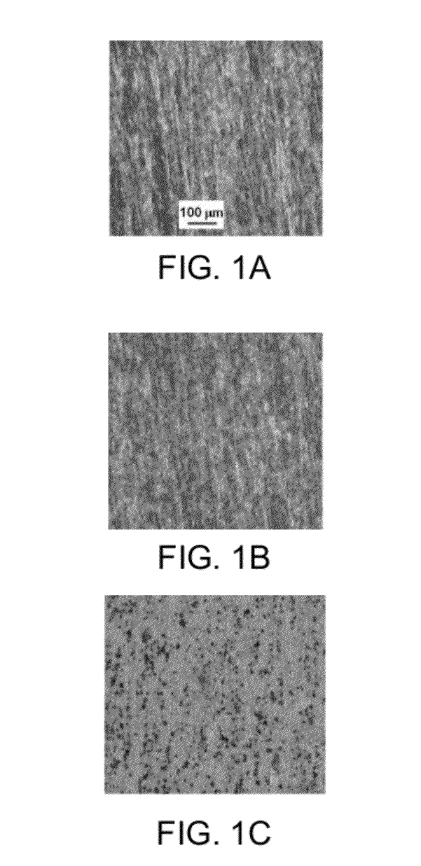

FIG. 1A is an optical microscope image of untreated aluminum. FIG. 1B is an optical microscope image of an aluminum surface treated with a “nanocoating process” similar to that described by Kwark et al., Nanocoating Characterization in Pool Boiling Heat Transfer of Pure Water,” International Journal of Heat and Mass Transfer, 53 (2010) 972-981. The following summarizes the procedure.

Al₂O₃ nanofluids are prepared by weighing the appropriate quantities of nanoparticles using a precision balance and then dispersing them into the appropriate volume of absolute ethanol in order to yield the desired concentration. For example, 2 grams of nanoparticles are dispersed in 2 L of ethanol. The nanoparticle dispersion is then subjected to an ultrasonic bath for 2 hours. This provides a nanofluid with 1 g/L of aluminum oxide in an ethanol carrier. The metal surface is then submerged in the nanofluid and a constant heating power is applied to the surface, in one example, 500 kW/m² is applied for 2 minutes. In the disclosed boiling process, as vapor bubbles grow over the heated metal surface, the evaporating liquid leaves behind nanoparticles which accumulate on and attach to the surface at the base of the bubbles. Various types of and thicknesses of nanocoatings can be prepared in this manner by varying the concentration, heating power and time.

As evidenced in FIG. 1B, nanoparticle coatings produced by this method suggest that the coatings are ultra thin, i.e., approximately 1-3 μm in thickness. Although a coating such as that depicted in FIG. 1B can assist in protecting the underlying metal against corrosion, the coating is not durable under aggressive handling, rubbing, or long term use and exposure.

FIG. 1A is an optical microscope image of untreated aluminum, whereas FIG. 1C is an image of aluminum which surface has been modified by the disclosed process. Comparing FIG. 1A and FIG. 1B, the original surface in FIG. 1A is only slightly discernable through the nanocoating. Whereas most of the hydrophilic layer is visible in FIG. 1C, thereby providing a modified surface to the aluminum substrate that increases the wettability of the surface.

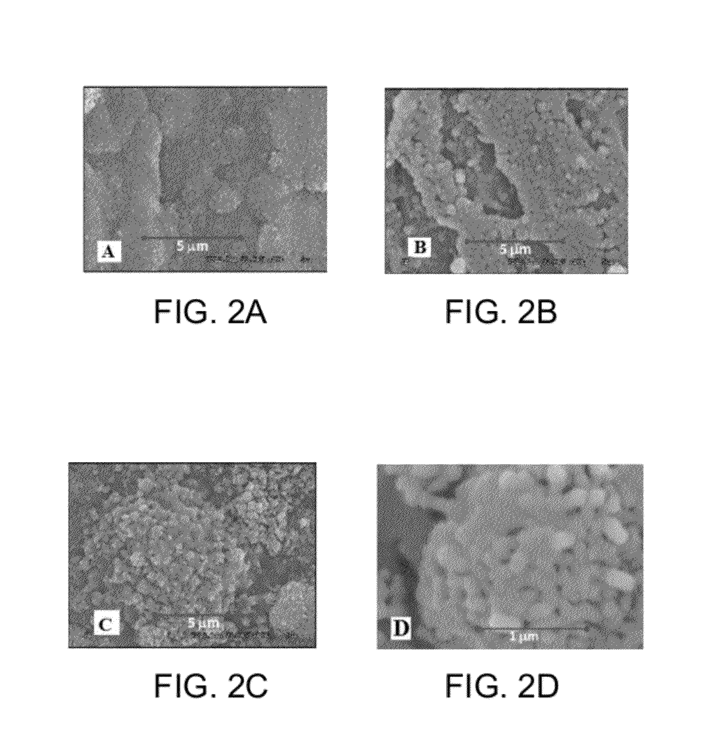

FIG. 2A is a scanning electron microscope image of an aluminum surface modified by the Boehmite process. The Boehmite process is a prior art process wherein the aluminum surface to be coated is immersed in a supersaturated sodium aluminate solution at a temperature below 100° C. (For an updated modification of the Boehmite process see Wang Z. et al., “Adjustment on gibbsite and boehmite co-precipitation from supersaturated sodium aluminate solutions.” Trans. Nonferrous Met. Soc. China, 20(2010) 521-527). FIG. 2B is a scanning electron microscope image of an aluminum surface modified by the “nanocoating process.” The coated substrate depicted in FIG. 2B depicts a minor degree of nanoparticle distribution relative to that depicted in FIG. 2C which is a scanning electron microscope image of an aluminum surface modified by the disclosed process. FIG. 2D is a further magnification of the surface depicted in FIG. 2C showing the surface roughness due to the fusing of the nanoparticles which provides stronger bonding to the aluminum surface and durability of the coating.

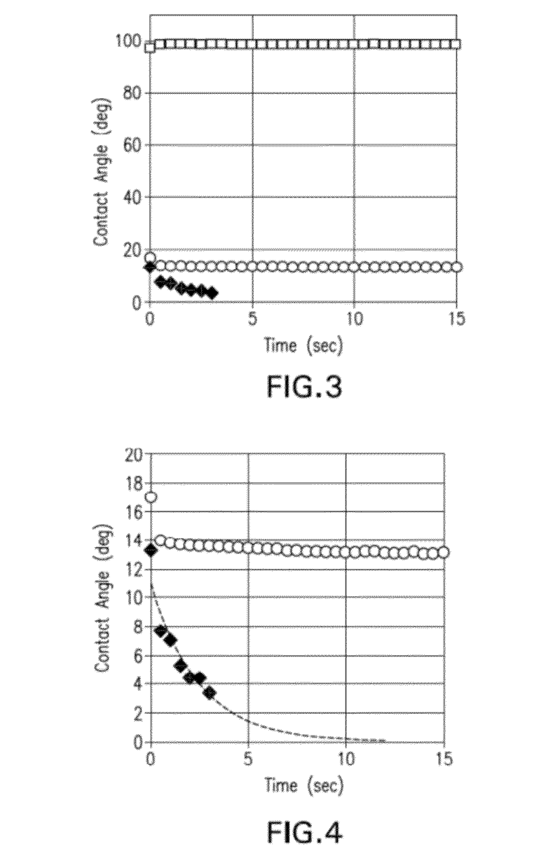

FIG. 3 depicts the change in contact angle when a drop of water is placed upon untreated aluminum (▪), aluminum treated by the nanocoating process (), and an aluminum substrate treated by the disclosed process (♦). As seen in FIG. 3 the contact angle of the untreated aluminum remains virtually constant over time indicating no spreading of the water. The surface prepared by the nanocoating process has a reduced contact angle, however, the system reaches equilibrium and the contact angle remains at approximately 13° to 14°. The surface prepared by the disclosed process provides a dynamic hydrophilic surface wherein the contact angle continues to decrease over time.

FIG. 4 is an enlargement of FIG. 3 indicating that the change in contact angle for aluminum treated with a nanocoating () versus aluminum treated by the disclosed process (♦). As shown, the contact angle for a water droplet on the surface formed by the disclosed process approaches the theoretical limit of 0° within 15 seconds.

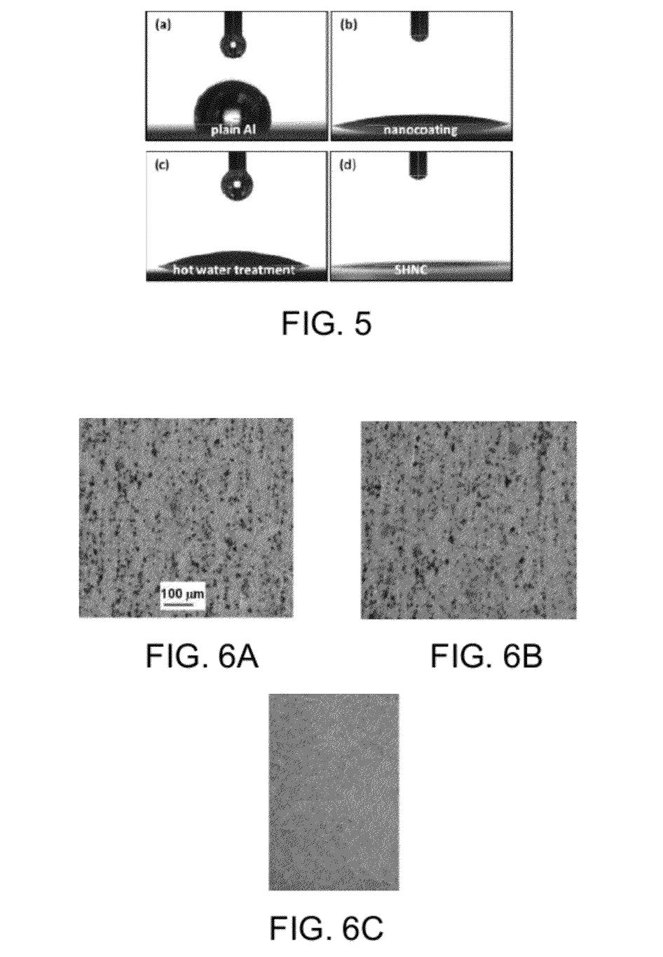

FIGS. 5A to 5D are photographs depicting the spreading of a 21 _{[}μL water droplet over various surfaces after 2 seconds of contact. FIG. 5A shows the spreading of a droplet over untreated aluminum wherein the contact angle, θ, was measured to be 99°. FIG. 5B shows the spreading of a droplet over aluminum treated with a nanocoating by the prior art nanocoating process wherein the contact angle, θ, was measured to be 14°. FIG. 5C shows the spreading of a droplet over aluminum receiving only treatment in a hot water bath wherein the contact angle, θ, was measured to be 22°. FIG. 5D shows the spreading of a droplet over aluminum which surface has been modified by the disclosed process wherein the contact angle, θ, was measured to be 4°.

FIG. 6A is an optical microscope image of an aluminum surface modified by the disclosed process prior to applying a tape peel test as described herein. FIG. 6B is an optical microscope image of the surface depicted in FIG. 6A showing that the modified surface peals adhesive from the tape during the tape peel test and the modified surface remains unchanged. FIG. 6C is an optical microscope image of the tape used in testing the surface depicted in FIG. 6A showing the loss of adhesive.

The contact angle of a water droplet on a hydrophilic surface prepared by the disclosed process was tested over time. The results are disclosed below in TABLE II herein below.

TABLE II

| Time | |
|---|---|
| (months) | Results* |
| 1 | contact angle <5° |
| 2 | contact angle <5° |
| 3 | contact angle <5° |
| 4 | contact angle <5° |
| 5 | contact angle <5° |
| 6 | contact angle <5° |
| 7 | contact angle <5° |
| 8 | contact angle <5° |
| 9 | contact angle <5° |
| 10 | contact angle <5° |
| 11 | contact angle <5° |
| 12 | contact angle <5° |
| 13 | contact angle <5° |
| 14 | contact angle <5° |
| 15 | contact angle <5° |
| 16 | contact angle <5° |

*The initial contact angle, however, as depicted in FIG. 4, the contact angle immediately approaches 0° due to the rapid spreading to the test liquid.

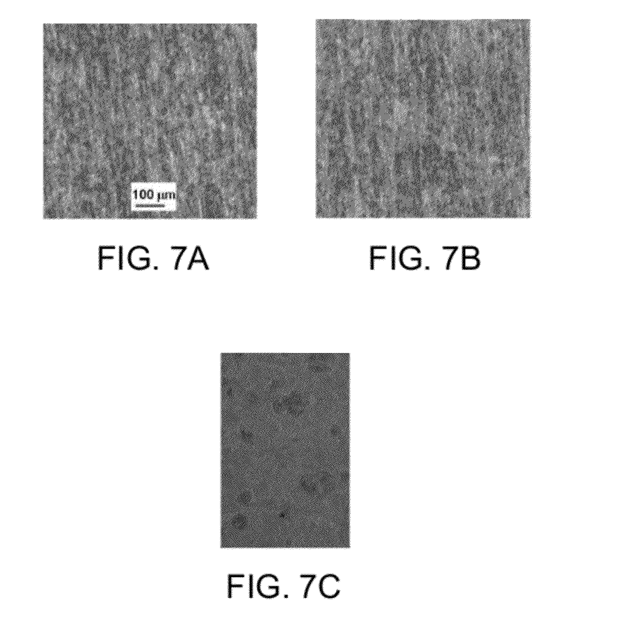

FIG. 7A is an optical microscope image of an aluminum surface coated with nanoparticles according to the nanocoating process before applying a tape peel test. FIG. 7B shows that the surface depicted in FIG. 7A loses a part of the coating during the tape peel test. FIG. 7C shows that the adhesive on the tape is intact, which means was not peeled by the coating.

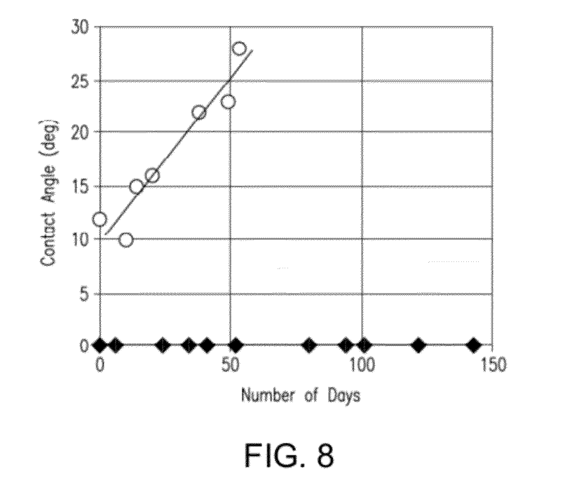

FIG. 8 confirms that the surfaces prepared by the disclosed process are durable surfaces in that they do not lose their hydrophilic properties once exposed to ambient conditions. Surfaces prepared by the Boehmite process () begin to lose their hydrophilic properties within a matter of days. Surfaces prepared by the disclosed process (♦), however, retain their superior hydrophilic properties for months without change. This indicates the high durability of the disclosed hydrophilic surfaces.

### EXAMPLE 1

A vessel large enough to contain sufficient water such that the substrate to be modified can be completely immersed, is heated until the water boils. A grease-free aluminum coupon is immersed in the boiling water for approximately 1 hour. The coupon is then removed from the water avoiding contact with the coupon face by sources of grease or oils, i.e., human touch, and the water removed. Any excess water can be removed by a clean absorbent material or by blow drying. The coupon is now ready for evaluation.

### EXAMPLE 2

Preparation of Nanofluid: 1 g of aluminum oxide having a desired particle size is charged to a vessel containing 1 L of an alcohol. Ethanol and isopropyl alcohols serve as convenient carriers when preparing alcoholic nanofluids. The mixture is agitated until the aluminum oxide is dispersed after which time the vessel containing the nanofluid is placed in an ultrasonic bath for 2 hours.

Preparation of the Substrate: The surface of the aluminum to be coated is sanded using 600-b grit or similar sand paper to removed any oils or grease and to provide a smooth surface. The test surface is then cleaned in an ultrasonic bath comprising a cleaning solvent, for example, acetone or an alcohol The coupon is then rinsed with the same solvent or distilled water and dried as described above.

Apparatus. Controlled and uniform heating power provides control of coating thickness and uniformity. One non-limiting method can be to place a resistive heater, such as a rubber strip heater, firmly against one side of the metal coupon. The heater should desirably be of the same shape and dimensions as the metal surface. To insure proper thermal contact and firm attachment one convenient method is to apply thermal interface grease to the heater before pressing it against the aluminum coupon.

Completely submerge the aluminum surface with attached heater, in the prepared nanofluid which is at or near room temperature. The surface to be coated need not be perfectly level, as long as it is not facing down. Turn on the power supply and by properly setting the voltage and current, an amount of power, for example, 500 kW/m² is delivered to the heater. Maintain the applied power level for 2 minutes. The nanocoating is formed during this time as the surface boils. Remove the substrate/heater assembly from the nanofluid, rinse with pure alcohol and blow dry. Detach the heater from the substrate and thoroughly wipe thermal grease residue from the aluminum with a paper towel or cotton swabs soaked in alcohol. To obtain coatings of various thicknesses, the nanofluid concentration, the duration of heating power or the power level can be varied.

### EXAMPLE 3

Preparation of Nanofluid. 1 g of aluminum oxide having a desired particle size is charged to a vessel containing 1 L of an alcohol. Ethanol and isopropyl alcohols serve as convenient carriers when preparing alcoholic nanofluids. The mixture is agitated until the aluminum oxide is dispersed after which time the vessel containing the nanofluid is placed in an ultrasonic bath for 2 hours.

Preparation of the Substrate: The surface of the aluminum to be coated is sanded using 600-b grit or similar sand paper to remove any oils or grease and to provide a smooth surface. The test surface is then cleaned in an ultrasonic bath comprising a cleaning solvent, for example, acetone or an alcohol The coupon is then rinsed with the same solvent or distilled water and dried as described above. Quenching Method. A hot plate is heated until the surface temperature is approximately 300° C. The substrate to be tested is placed on the hot plate for 2 minutes. Note the surface to be coated is not the surface in contact with the hot plate. A grease or oil-free means is used to then submerge the substrate in the nanofluid which is at an initial temperature at or near room temperature. Once boiling begins, the substrate is held in the nanofluid until evidence of boiling ceases, i.e., no longer formation of bubbles on the substrate surface etc. This cycle is repeated 5 more times. To increase the hydrophilic nanoparticle coating, the formulator can repeat the cycle additional times.

Evaporation method to produce the nanocoating. A hot plate is heated to approximately 50° C. The substrate to be coated is sprayed with the nanofluid. Excess fluid is removed leaving only the wetting film. The substrate is placed on the hot plate with the coated surface up. Once dried, the formulator can repeat this step to provide coatings of varying properties.

The coating can also be applied by spin-coating in a spin-coating machine. Select an amount of nanofluid having a volume sufficient to spread over the entire substrate. Deposit the nanofluid onto the center of the stationary substrate. Select spin rpms and durations of rpms and initiate rotation. The centrifugal force of rotation spreads the nanofluid into a thin-film over the rotating substrate, and as the nanofluid spreads and thins out it automatically evaporates leaving behind the nanoparticles on the surface.

Fixing the Nanoparticle Coating. A substrate described above is submerged into boiling water for approximately 1 hour. The resulting substrate comprises the disclosed hydrophilic nanoparticle coating.

### EXAMPLE 4

Photograph the surface to be evaluated in an optical microscope at selected magnifications. Using scissors cut a 1.5 inch or longer segment of 3M 2517 Scotch tape. Uniformly press at least about 1 inch of the segment against the coated side of the coupon, insuring even contact throughout. Provide sufficient excess unattached length to provide a finger hold. Grabbing the finger hold, pull the tape away from the surface in one swift motion. Photograph the surface again at the same magnifications used before pulling the tape to record any peeling of the coating. Also photographically record any coating residue or change on the adhesive side of the peeled tape.

The following are non-limiting examples of the use of the disclosed hydrophilic surfaces and aluminum substrates prepared by the disclose process.

The disclosed process provides for a durable coating for aluminum substrates having enhanced hydrophilic properties desirable to the user of aluminum. One non-limiting embodiment of the disclosed hydrophilic nanocoating takes advantage of the enhanced wickability of the disclosed surfaces, for example, aluminum sintered wicks. The increased rate of cooling fluid delivery to a heated zone can substantially either remove wick drying or substantially delay wick drying thereby providing an operating temperature in a heated zone to be maintained through higher operating powers of the electronics. In addition, the delivered liquid can form a thinner layer over the heated zone, thereby evaporating faster, and hence lower the surface temperature of the heated zone for a given power density. Because of the durability of the disclosed surfaces, heat pipes and wick-based heat sinks can be permanently sealed after charging with the working fluid.

The hydrophilic coatings disclosed herein can be used to prepare aluminum substrates that allow water vapor to condense as a thin film over the fins of air-conditioning evaporator coils, rather than into slugs or large droplets that can clog the spaces between fins. The thin films formed over the aluminum surfaces would allow for unimpeded and uniform air flow over the whole assembly of cooling coils. This would reduce the amount of condensate that would carry over into the air conditioning duct work. Specifically, because evaporator coils are narrowly spaced, the enhanced durability surfaces would not be subject to additional rough handling or unwanted abrasive forces.

Falling film evaporators configured either horizontally or vertically can make use of the aluminum substrates disclosed herein. In use a cooling liquid is sprayed over a heated tube bundle or the cooling liquid cascades within heated vertical tubes. An apparatus comprising the disclosed aluminum substrates will have the cooling fluid more uniformly spread along the entire perimeter of any tubes or other evaporative means, i.e., rather than only the portion exposed to the spray, or only the portion under inlet ports in the vertical tubes. As such, for a given surface area of tubing the heat input and liquid delivery rate, higher amounts of vapor or distillate can be generated.

What is claimed is:

1. A process for preparing a hydrophilic surface on aluminum, comprising:
a) applying to aluminum a nanoparticle coating; and
b) fixing the nanoparticle coating to the aluminum.

2. The process according to claim 1, wherein the nanoparticle coating comprises aluminum oxide.

3. The process according to claim 1, wherein the nanoparticle coating comprises nanoparticles having a size of less than about 100 nm in diameter.

4. The process according to claim 1, wherein the nanoparticle coating comprises nanoparticles having a size from about 50 nm to about 100 nm in diameter.

5. The process according to claim 1, wherein the nanoparticle coating comprises nanoparticles having a size of from about 10 nm to about 90 nm in diameter.

6. The process according to claim 1, wherein the nanoparticle coating comprises nanoparticles having a size of from about 20 nm to about 50 nm in diameter.

7. The process according to claim 1, wherein a liquid applied to the hydrophilic surface has a contact angle less than about 5°.

8. The process according to claim 1, wherein when water is applied to the hydrophilic surface water has a contact angle less than about 5°.

9. The process according to claim 1, wherein a liquid applied to the hydrophilic surface spreads such that the contact angle is less than about 1°.

10. The process according to claim 1, wherein when water is applied to the hydrophilic surface water has a contact angle less than about 1°.

11. A process for forming a hydrophilic surface on an aluminum substrate, comprising:
a) contacting an aluminum substrate with a composition comprising:
i) aluminum oxide; and
ii) one or more carriers;
to form a nanoparticle coating on the aluminum substrate; and
b) fixing the coating by heating the aluminum substrate in a fixing solution.

12. The process according to claim 11, wherein the composition in step (a) is a nanofluid.

13. The process according to claim 11, wherein the composition of step (a) comprises one or more organic solvents.

14. The process according to claim 13, wherein the one or more organic solvents is chosen from ethanol, isopropanol, or a mixture thereof.

15. The process according to claim 12, wherein the nanofluid comprises water.

16. The process according to claim 12, wherein the nanofluid comprises from about 0.01 g/L to about 2 g/L of alumina, ceramic material, or mixtures thereof.

17. The process according to claim 12, wherein the nanofluid comprises from about 0.01 g/L to about 2 g/L of alumina

18. The process according to claim 12, wherein the nanofluid comprises from about 0.5 g/L to about 1.5 g/L of alumina

19. The process according to claim 12, wherein the aluminum substrate is contacted with the nanofluid once.

20. The process according to claim 12, wherein the aluminum substrate is contacted with the nanofluid more than once.

21. The process according to claim 11, wherein the fixing solution is water.

22. The process according to claim 11, wherein the temperature of the fixing solution is approximately 100° C.

23. The process according to claim 11, wherein the temperature of the fixing solution is from about 95° C. to about 100° C.

24. The process according to claim 11, wherein the nanocoating is applied to the substrate in step (a) by the evaporative method.

25. The process according to claim 11, wherein the nanocoating is applied to the substrate in step (a) by the quenching method.

26. An aluminum substrate having a hydrophilic surface characterized in that when a 21 μL drop of water is contacted with the hydrophilic surface, the measured contact angle is less than about 8° is 2 seconds.

27. The substrate according to claim 26, wherein the hydrophilic surface comprises aluminum oxide nanoparticles.

28. The substrate according to claim 26, wherein the hydrophilic surface comprises a mixture of aluminum oxide and ceramic nanoparticles.

29. The substrate according to claim 26, wherein the substrate comprises more than one hydrophilic surface.

30. The substrate according to claim 26, in the shape of a solid rod, a pipe, a coil or a sheet.
